(19) United States
(12) Patent Application Publication
(10) Pub. No.: US 2024/0322062 A1
(43) Pub. Date: Sep. 26, 2024

(54) Light Sensitive Semiconductor Structures

(71) Applicant: X-FAB Global Services GmbH, Erfurt (DE)

(72) Inventors: Daniel Gäbler, Apolda (DE); Pablo Siles, Erfurt (DE); Qiang Ai, Kuching (MY); Tamer Abdulrahman, Évry (FR); Tong Hong Tan, Sarawak (MY)

(21) Appl. No.: 18/609,943

(22) Filed: Mar. 19, 2024

(30) Foreign Application Priority Data
Mar. 20, 2023 (GB) 2304001.7
Jul. 12, 2023 (GB) 2310724.6

(51) Int. Cl. H01L 31/112; H01L 31/0224; H01L 31/18

(52) U.S. Cl. CPC H01L 31/1126; H01L 31/022408; H01L 31/182

(57) ABSTRACT

A method of forming a light sensitive semiconductor structure is provided. The method includes providing a semiconductor wafer comprising a semiconductor layer comprising a light sensitive region, providing a gate structure comprising an insulation layer on said semiconductor layer and a polysilicon layer on said insulation layer, providing a contact stop layer on said gate structure, wherein said contact stop layer covers said light sensitive region, providing an etch mask, etching said contact stop layer using said etch mask to form said opening, etching said polysilicon layer using said etch mask, and providing a plurality of metal layers comprising a first metal layer electrically connected to said semiconductor layer and a plurality of dielectric layers between metal layers of said plurality of metal layers.

### BACKGROUND

Photodiodes are used in a wide range of applications for detecting and measuring electromagnetic radiation. The high refractive index of the semiconductor material can cause a significant amount of light to be reflected before it enters the light sensitive region of the photodiode, with the result that this light is not available for sensing and the quantum efficiency of the device is degraded.

The reflection losses can be reduced by creating a graded index using an effective medium by forming a layer comprising different proportions of materials having different refractive indices. Using shallow trench isolation (STI), relatively small features can be etched in the surface of the semiconductor material and filled with silicon oxide to create an effective medium in order to reduce reflection losses.

Other materials in the path of the incident light may absorb a proportion of light, which can further reduce the amount of light reaching the light sensitive region. In some cases, the oxide layers above the light sensitive region can be etched to form a window and thereby reduce the absorption.

However, there is a continued need for improvements to the sensitivity and durability of photodiodes.

### SUMMARY

Aspects of the invention provide semiconductor structure and a method of forming such as set out in the appended claims.

The semiconductor structure comprises gate structure and a contact stop layer on the gate structure, with an opening in the contact stop layer located over the light sensitive region. A polysilicon layer of the gate structure is used as an etch stopping layer when forming the opening in the contact stop layer. By providing an opening in the contact stop layer over the light sensitive region, absorption losses can be reduced.

Embodiments will now be described with reference to the accompanying drawings.

### BRIEF DESCRIPTION OF DRAWINGS

FIG. 1A to 1F show a schematic cross section of a semiconductor structure in a sequence of steps;

FIG. 1G shows a schematic cross section of a semiconductor structure provided from another sequence of steps;

FIG. 2 shows a schematic cross section of a semiconductor structure comprising a light detection region and a transistor region;

FIG. 3 shows a flow diagram illustrating the steps of a method of forming a semiconductor structure;

FIG. 4 shows a schematic cross section of a part of a semiconductor structure comprising a photodiode;

FIG. 5 shows a schematic cross section of a part of a photodiode;

FIG. 6 shows a graph of a doping profile of a photodiode;

FIG. 7A to 7F show a sequence of schematic diagrams illustrating a method of forming a photodiode;

FIG. 8 shows a schematic top view of a semiconductor structure comprising a photodiode; and

FIG. 9 shows a flow diagram illustrating the steps of a method of forming a photodiode.

### DETAILED DESCRIPTION

Embodiments described herein provide light sensitive semiconductor structures (e.g. complementary metal oxide semiconductor (CMOS) ultraviolet (UV) photodetectors) and methods of forming such semiconductor structures, which can provide improved coupling of incident light into the light sensitive region of the structure. The skilled person will understand a CMOS process to involve a large number (sometimes over 100) process steps. The CMOS process may comprise at least the following process steps:
Providing a N or P type doped silicon wafer;
Forming one or more isolation wells of the opposite doping type to the wafer;
Providing lateral isolation (e.g. Field Oxide, or trench isolation, typically STI);
Forming a gate complex (gate oxide growth, poly gate formation including spacers);
Forming the source and drain (comprising n or p type shallow high dose doping);
Forming (electrical) contacts (e.g. comprising a silicidation process, isolation layer and metallization, typically in multiple layers connected by VIAs);
Forming passivation (e.g. comprising a silicon nitride layer to protect the semiconductor wafer);
Forming connection pad openings (e.g. comprising mask-defined removal of passivation and isolation layers on top of a landing metal area used for electrical connections, e.g. by bond wires).

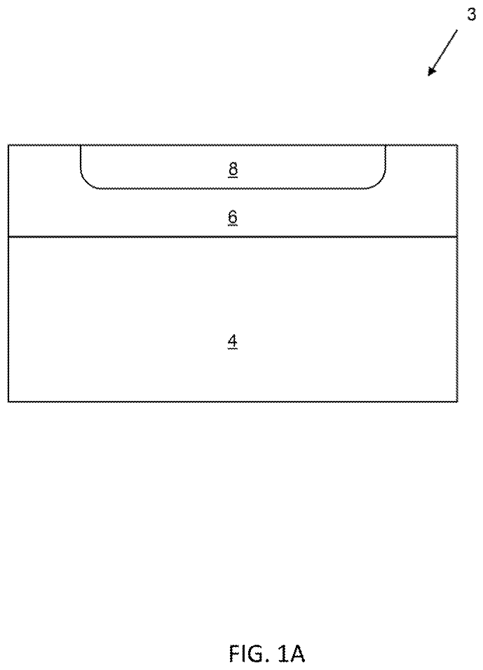

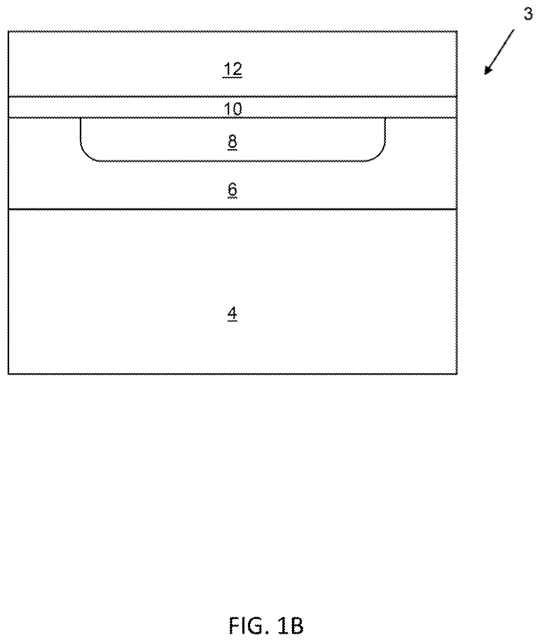

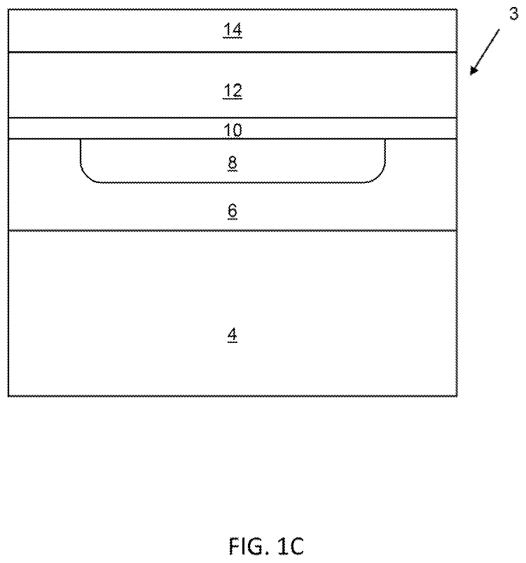

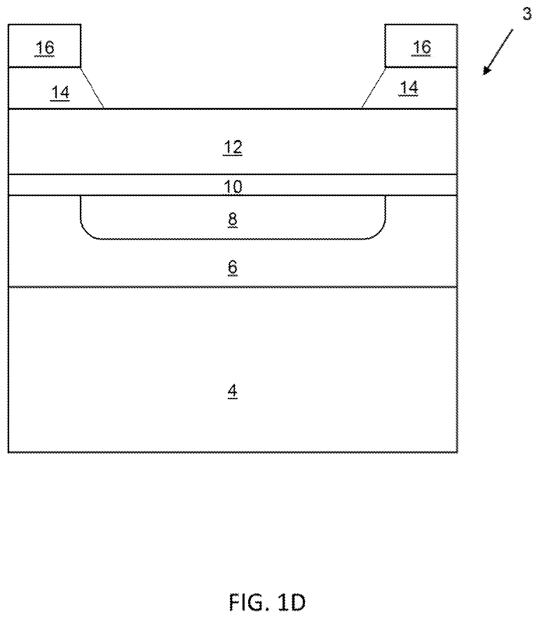

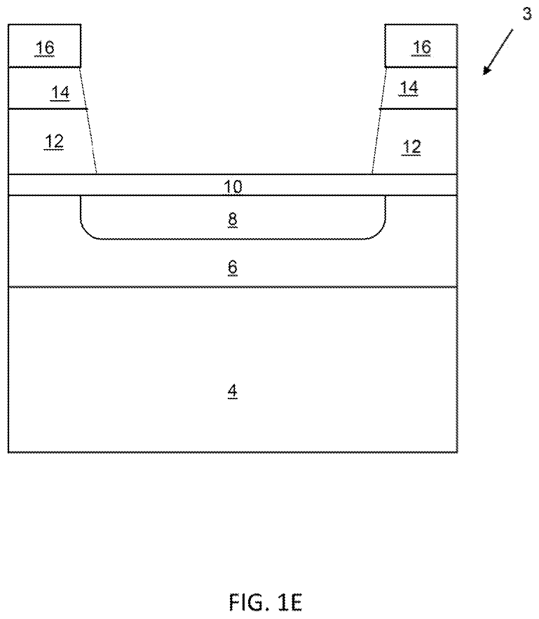

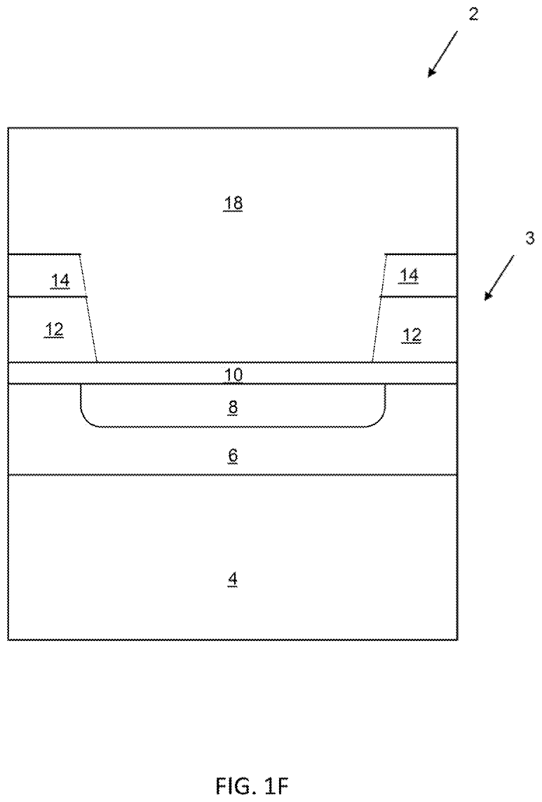

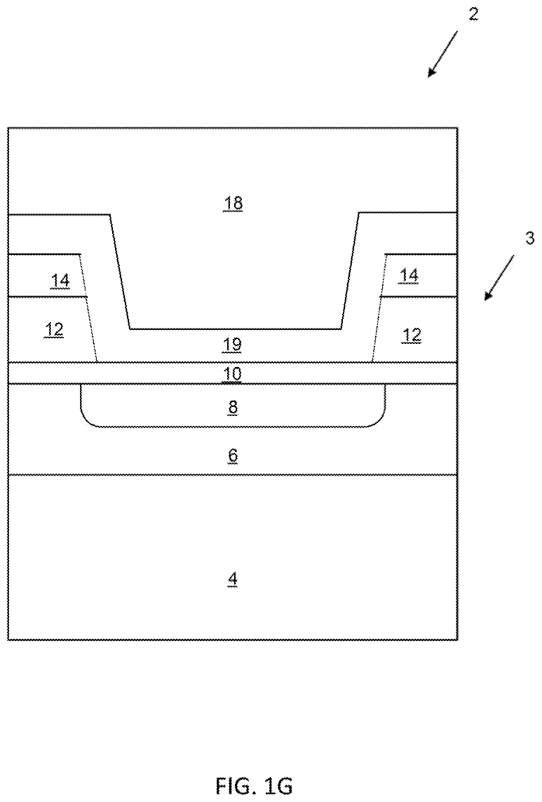

FIGS. 1A to 1F illustrate the steps of a method of forming a semiconductor structure 2 by showing successive schematic cross sections of a part of the semiconductor structure 2. The same reference numerals have been used for the same or similar features in different figures for ease of understanding and are not intended to limit the illustrated embodiments.

FIG. 1A shows a silicon wafer 3 comprising a silicon substrate 4 and a top silicon layer 6 comprising a light sensitive region 8 (a.k.a. photosensitive region) typically comprising a PN-junction. The light sensitive region 8 may be formed by one or more doping steps, for example using a mask to inject dopants into the top silicon layer 6. The light sensitive region will typically form part of a photodiode of the completed semiconductor structure 2.

FIG. 1B shows the wafer 3 after providing an oxide layer 10 and polysilicon layer 12 on the wafer 3. The oxide layer 10 can be thermally grown from the silicon layer 6 and may have a thickness in the range of 5 to 100 nm. The oxide 10 may be the gate oxide layer which together with the polysilicon layer 12 form part of a gate structure of a transistor (not shown) on the wafer 3. The gate structure, which comprises parts of the same oxide layer 10 and polysilicon layer 12 as formed over the light sensitive region 8, is used to control the conductivity of a semiconductor area under it. Such transistors are formed in other regions of the wafer 3, and have the same gate structure provided by the oxide layer 10 and polysilicon layer 12 formed over the light sensitive region 8 as shown in FIG. 1B.

FIG. 1C shows the wafer 3 after providing a contact stop layer (CSL) 14, which is used to protect the underlying silicon in a later etch step when providing contacts to the photodiode or to other semiconductor devices of the semiconductor structure 2. The CSL 14 stops the contact etch before reaching the underlying silicon (or silicide) and allows the etching process to be changed for a soft landing. The contacts may be formed by etching trenches down to the silicon, filling the trenches by metal deposition, and optionally followed by annealing. The CSL 14 may be used when forming contacts in a CMOS process. The contact stop layer can have a thickness in the range of 10 nm to 100 nm, for example 40 nm.

FIG. 1D shows the wafer 3 after providing an etch mask 16 and etching the CSL 14 to provide an opening in the CSL 14. A dry etch is used to locally remove the CSL 14. The polysilicon layer 12 is used as an etch stop layer. The etch mask 16 determines the lateral position and the width of the opening formed over the light sensitive region 8 in the CSL 14. The opening may cover/overlap the whole or a major part of the light sensitive region 8. The etch mask 16 may be a resist mask. Removing the CSL 14 can increase the amount of incident UV light reaching the light sensitive region 8 of the finished semiconductor structure.

FIG. 1E shows the wafer 3 after performing a second etch to remove a part of the polysilicon layer 12 over the light sensitive region 8. The second etch also comprises a dry etch. The same etch mask 16 is used to perform the second etch. The etch may comprise a plasma-supported process, in which the polysilicon layer 12 is removed selectively and the etching chemistry in particular is very selective in relation to the oxide layer 10, so that the plasma etching process stops reliably in the oxide layer 10, even for a very thin oxide layer. The oxide layer 10 can be left in place over the light sensitive region 8, as it has a relatively small impact on the light coupling.

FIG. 1F shows the semiconductor structure 2 after removing the etch mask 16 and depositing dielectric layers 18. The dielectric layers 18 (also referred to as “interdielectric layers”) separate and provide insulation between metal layers (not shown). The metal layers are provided for connecting to the light sensitive region 8 in order to form light sensitive semiconductor device such as a photodiode and for connecting to other doped regions in the silicon layer 6 for forming further semiconductor devices of the semiconductor structure 2 such as transistors. The finished structure 2 may be a UV photodetector for detecting incident UV light. In use, light incident on and absorbed in or close to the light sensitive region 8 of such a photodetector generates charge carriers, which give rise to a measureable current when a voltage is applied across the light sensitive region 8.

FIG. 1G shows an alternative embodiment where an anti-reflective coating (ARC) layer 19 is provided over the light sensitive region 8 between the upper silicon layer 6 and the dielectric layers 18. The ARC layer 19 typically comprises a dielectric layer. The environment for providing an ARC layer 19 at this stage can be beneficial. There is only a very thin (high quality and well controlled) gate oxide layer 10 on the silicon surface and the deposited ARC layer 19 acts without disturbing influences of a CSL layer. Also, as at this point in the manufacturing process, the ARC layer 19, can be chosen relatively freely as it has no additional purposes (e.g. etch stop function etc.). Hence, the material of the ARC layer 19 can be chosen to be optimal for the target application (e.g. for a particular wavelength range). For example, the ARC layer 19 may comprise a nitride layer with low absorption in blue/UVA range and with a relatively high refractive index of about two, to get a good reflection reduction for the critical blue range. The ARC layer 19 placed at this process stage provides a solution with no impact on the silicon layer 6 and with small side effects on the photodiode build.

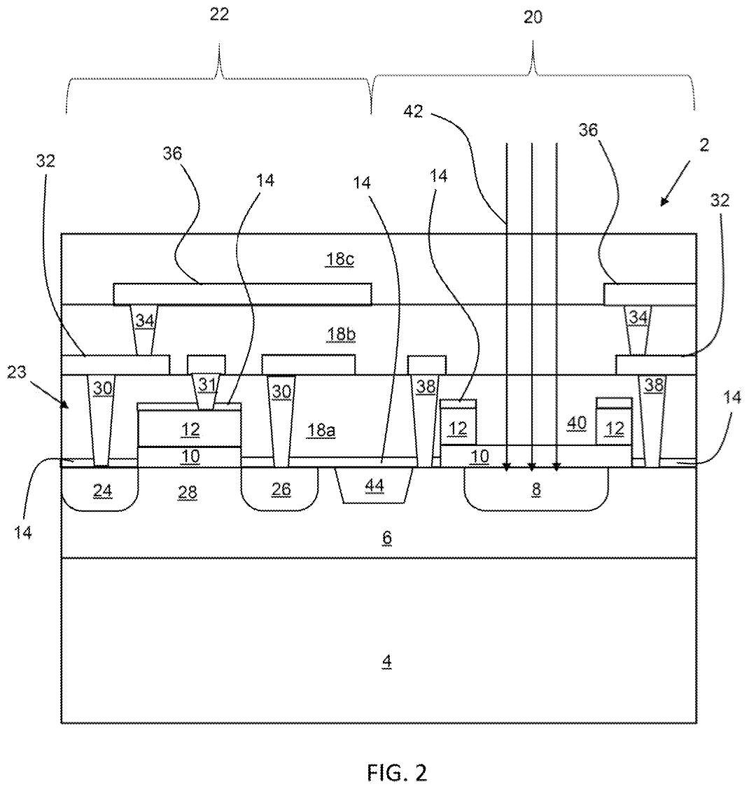

FIG. 2 shows a schematic cross section of a semiconductor structure 2 (e.g. a CMOS photodetector) comprising a light detection region 20 and a transistor region 22. The semiconductor structure 2 may be the semiconductor structure 2 formed as described in relation to FIGS. 1A to 1F above. The transistor region 22 comprises a transistor 23 comprising a drain region 24 and a source region 26 separated by a channel region 28. A gate structure comprising the oxide layer 10 and polysilicon layer 12 is located above the channel region 28 for controlling the transistor 23 by changing the conductivity in the channel region 28. The gate structure of the transistor 22 may further comprise spacers (not shown) such as nitride spacers. Metal contacts 30 are connected to the drain and source regions and to a metal layer 32 being the first (lowest) metal layer. A gate contact 31 is connected to the polysilicon layer 12 over the channel region 28 (i.e. connected to the gate of the transistor 23). VIAs 34 connect the first metal layer 32 to a second metal layer 36. The semiconductor structure 2 may comprise further metal layers (not shown) including a top metal layer for external connections to the semiconductor structure 2. For example, the semiconductor structure may comprise four to eight metal layers. The metal layers 32, 36 are separated from each other and from the silicon 6 by dielectric layers 18a-c. The light detection region 20 comprises the light sensitive region 8 in the silicon 6 for detecting incident light. The light sensitive region 8 comprises a pn-junction between a p-doped region and an n doped region. For example, the pn-junction may be formed by an n-doped well in a p-doped silicon layer 6. Contacts 38 are connected to the silicon layer 6 and are configured to apply a voltage across the light sensitive region 8 (i.e. across the pn-junction of the light sensitive region 8). The contacts 38 are connected to the first metal layer 32. There is an opening 40 in the polysilicon layer 12 and the CSL 14 over the light sensitive region. Light 42 incident on the light detection region 20 is transmitted through the opening 40 to the light sensitive region 8, where the light 42 can be detected. The light detection region 20 and the transistor region 22 are laterally isolated from each other by isolation region 44, which may comprise shallow trench isolation (STI).

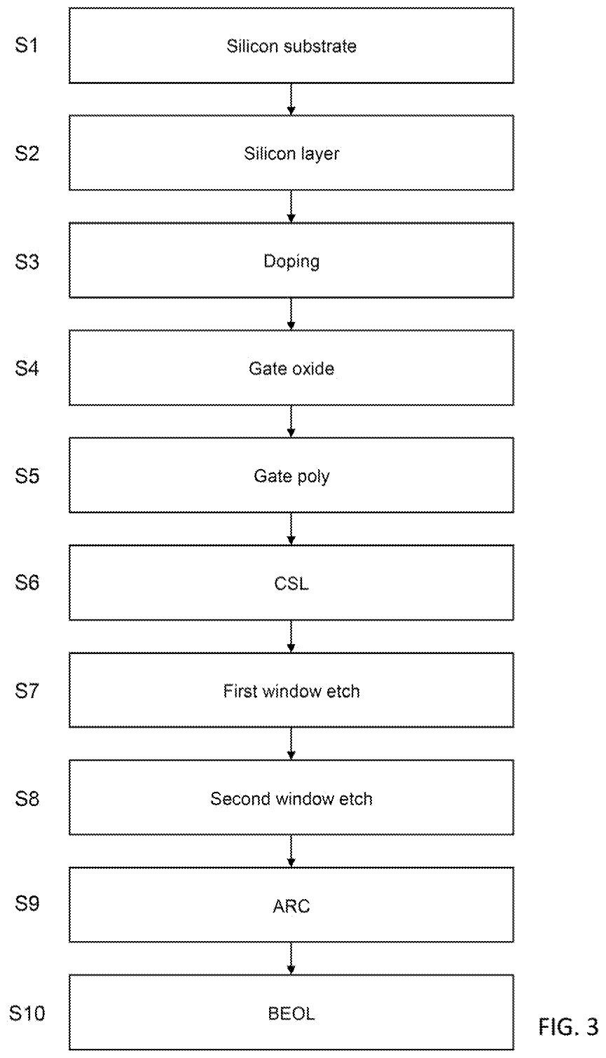

FIG. 3 shows a flow diagram illustrating at least some of the steps of a method of forming the semiconductor structure 2 illustrated in FIG. 2 described above. The steps may be performed as part of a CMOS process.
S1. Providing a silicon substrate 4 (a.k.a. the handling wafer).
S2. Providing a silicon layer 6 on the handling wafer 4, for example by epitaxial growth.
S3. Doping the silicon layer 6 to form the light sensitive region 8 and the drain and source regions 24, 26. The doping may comprise a plurality of individual doping steps with different dopants, implantation energies, angles of incidence etc.
S4. Forming a gate oxide layer 10 on the silicon layer 6, for example by thermal oxidation.
S5. Depositing a polysilicon layer 12 on the gate oxide layer 10, and patterning said polysilicon layer 12 to form gate structures of the semiconductor structure 2. The gate oxide 10 is typically also removed from the areas where the polysilicon layer 12 is removed. Importantly, a part of the polysilicon layer 12 over/covering the light sensitive region 8 remains after the patterning. The polysilicon layer 12 is also patterned to provide openings for any contacts 30, 38 that are going to be directly connected to the upper silicon surface 6.
S6. Depositing a contact stop layer (CSL) 14 on the wafer 3 covering the remaining polysilicon layer 12 and exposed areas of the upper silicon layer 6, which may be a silicided or non-silicided region.
S7. Using an etch mask, locally removing the CSL 14 at least over the light sensitive region 8 and using the polysilicon layer 12 as a first etch stop layer.
S8. Using the same etch mask, locally removing the polysilicon layer 12 at least over the light sensitive region 8. The gate oxide layer 10 is used as an etch stop layer to prevent damage to the light sensitive region 8.
S9. Optionally, providing an anti-reflective coating (ARC) layer 19 over the light sensitive region 8. The ARC layer 19 may comprise a dielectric layer. An ARC layer 19 can also be used to provide a graded refractive index to reduce reflections at the silicon interface. The ARC layer 19 can be deposited directly on the gate oxide 10 over the light sensitive region 8.
S10. Providing metal layers 32, 36 and dielectric layers 18a-c and forming contacts 30, 38 and VIAs 34 for connecting to the light sensitive region 8 and for connecting to the transistor 23. The remaining CSL 14 is used to control the contact etch when forming the contacts 30, 38. Typically step S10 is part of the back-end of line (BEOL) process of a CMOS process.

Steps S7 and S8 provide the opening over the light sensitive region which can significantly improve the coupling of UV light into the light sensitive region 8. The other method steps (S1 to S6 and S9 and S10) may be standard CMOS process steps as known in the art.

By selectively removing the CSL layer 14 over the light sensitive region 8, the amount of light absorbed before reaching the light sensitive region 8 can be reduced. In addition, by selective removal of the CSL layer 14, a potentially significant source of fixed charge is removed and incident UV light may thereby cause less of a degradation change. A photodiode with the CSL left over the light sensitive region 8 can be more susceptible to UV stress based degradation than the device without the CSL layer. UV stress occurs for light with wavelengths below 300 nm, and the effect gets stronger as the wavelength decreases. By removing the CSL layer 14 as described, a reduction of UV stress was found down to 200 nm, where the greatest degradation can occur.

In general, the present disclosure provides a method of forming a light sensitive semiconductor structure, the method comprises providing a semiconductor wafer (typically a silicon wafer) comprising a semiconductor layer (e.g. an epitaxial silicon layer) comprising a light sensitive region, and providing a gate structure comprising an insulation layer (e.g. an oxide layer) on said semiconductor layer and a polysilicon layer on said insulation layer. The method further comprises providing a contact stop layer on said gate structure, wherein said contact stop layer covers said light sensitive region, providing an etch mask, said etch mask determining a position and a width of an opening to be formed over said light sensitive region in said contact stop layer, and etching said contact stop layer using said etch mask to form said opening, wherein said polysilicon layer is used as a first etch stopping layer. After etching the contact stop layer, etching said polysilicon layer using said etch mask, wherein said insulation layer is used as a second etch stopping layer. The method further comprises providing a plurality of metal layers comprising a first metal layer electrically connected to said semiconductor layer and a plurality of dielectric layers between metal layers of said plurality of metal layers. The metal and dielectric layers are typically provided in a CMOS back-end-of-line (BEOL) process.

Providing said gate structure may comprise thermally growing an oxide layer being said insulation layer and depositing a polysilicon layer on said oxide layer. The oxide layer may have a thickness in the range of 3 to 100 nm, e.g. between 5 and 10 nm.

Providing said contact stop layer may comprise depositing one of a silicon nitride layer and a silicon oxynitride layer. Nitride rich layers tend to absorb a larger proportion of UV light.

The step of etching said contact stop layer may comprise a dry etch. The step of etching said polysilicon layer may also comprise a dry etch.

The method may further comprise forming metal contacts to connect to said light sensitive region in order to apply a voltage across said light sensitive region (to form a photodiode), wherein said contact stop layer is used as an etch stopping layer when forming said metal contacts.

The method may further comprise providing an anti-reflective coating, ARC, layer over said light sensitive region. The ARC layer may comprise a dielectric layer. The ARC layer can be directly deposited on the insulation layer. Alternatively or in addition, a layer of an effective medium having a refractive index between a refractive index of silicon oxide and a refractive index of silicon.

The method may further comprise shallow trench isolation (STI) to provide isolation around said light sensitive region. STI may also be used to provide the layer of the effective medium. The isolation and the effective medium may be provided by the same STI process steps. That is, only one step of etching and one step of filling with oxide may be used to form both the isolation and the effective medium.

The method may further comprise patterning said polysilicon layer to form a gate in a transistor region of said semiconductor structure. The same polysilicon layer that is etched to form the opening over the light sensitive region is used in a different region of the semiconductor structure to form a gate.

The method may further comprise forming a metal contact to connect to said gate, wherein said contact stop layer is used to as an etch stopping layer when forming said metal contact. The contact stop layer can provide a soft landing on the polysilicon gate when etching a trench for the metal deposition to form the gate contact.

The present disclosure further provides a semiconductor structure. The structure comprises a photodiode comprising a light sensitive region in a semiconductor layer, a gate structure comprising an insulation layer located on said semiconductor layer and a polysilicon layer located on said insulation layer, a contact stop layer located on said gate structure, and an opening in said contact stop layer and in said polysilicon layer located over at least a part of said light sensitive region. The opening can allow a larger proportion of UV light to reach the light sensitive region of the photodiode. The structure further comprises a plurality of metal layers comprising a first metal layer electrically connected to said semiconductor layer and a plurality of dielectric layers between metal layers of said plurality of metal layers. The metal layers are typically part of a CMOS backend stack and provide electrical connections to and/or between the semiconductor devices (such as the photodiode) of the structure.

The contact stop layer may comprise one of a silicon nitride layer and a silicon oxynitride layer. These nitride rich layers can provide good etch selectivity (e.g., to stop an oxide etch) but absorb a relatively large proportion of UV light.

The semiconductor structure typically comprises a number of other semiconductor devices and may comprise a transistor, wherein a gate of said transistor comprises a part of said gate structure. Hence, the gate structure provided over the light sensitive region is also provided over other regions of the semiconductor structure, where it can be patterned to form a gate of a transistor and where the contact stop layer is used when forming a gate contact.

A photodiode and method of forming a photodiode in a semiconductor structure is described in more detail below. Typically the semiconductor structure may comprise an array of such photodiodes to form a sensor such as a photodetector.

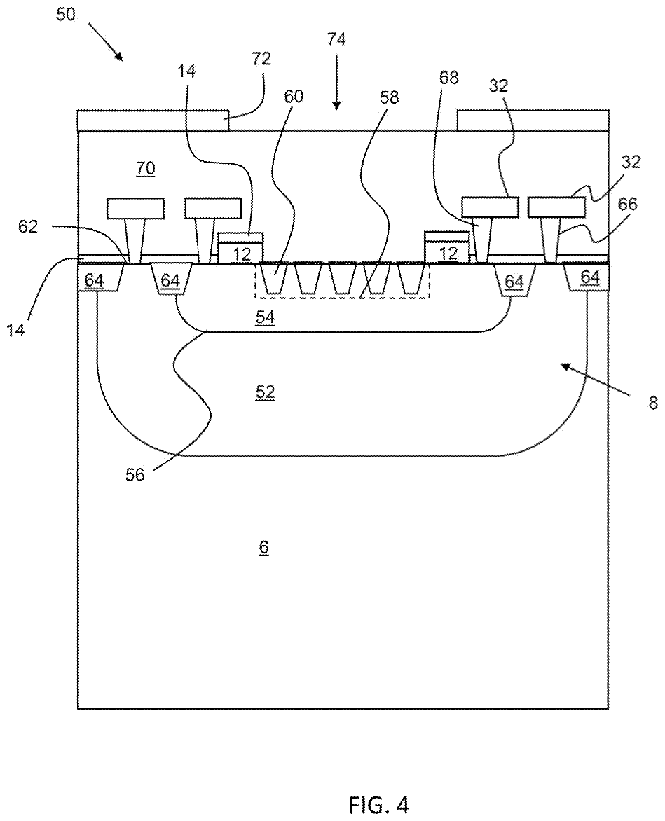

FIG. 4 shows a schematic diagram of a photodiode 50 for UV detection, which may be a photodiode 50 comprising the light sensitive region 8 of the semiconductor structure 2 as described in relation to FIGS. 1A to 1F and FIG. 2 above. The photodiode 50 comprises a silicon layer 6 comprising a first, n-doped, well 52 connected to the cathode of the photodiode 50, and a second, p-doped, well 54 connected to the anode of the photodiode 50. A pn-junction 56 is formed between the first well 52 and the second well 54. A patterned layer 58 being an effective medium comprising trenches 60 filled with oxide is located at the surface 62 of the silicon layer 6 in the second well 54 in order to reduce reflection losses at the interface. The trenches 60 may be round or hexagonal holes arranged in an array to cover the light sensitive area associated with the pn-junction 56. The different well regions 52 and 54 are separated along the surface 62 by STI 64. A cathode contact 66 is connected to the first well 52, and an anode contact 68 is connected to the second well 54. Both contacts 66 and 68 are connected to a first metal layer 32 of a backend stack 70 of the photodiode 50. The backend stack 70 also comprises a passivation layer 72, with a UV window 74 overlapping the light sensitive region of the photodiode 50. A second UV window is formed in the CSL 14. Carriers generated by light absorbed in the p-doped well 54 are pushed by the inherent electric field due to the continuously falling doping profile towards the pn-junction 56. In particular, the doping concentration in the silicon at the interface between the trenches 60 and the silicon in the second well 54 is increased and continuously decreasing away from the interface, thereby reducing the risk of charge carriers being influenced at the interface. This influence can be due to changes in the electric field. For example, if the dielectric layers on top of the silicon change their trapped charge level.

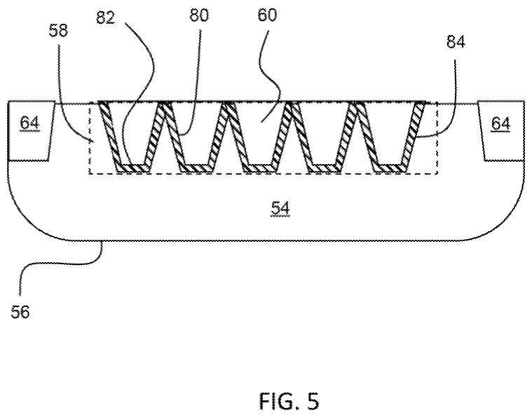

FIG. 5 shows an enlarged diagram of the second well 54 of the photodiode 50 shown in FIG. 4. The second well 54 comprises the patterned layer 58 comprising trenches 60 filled with oxide forming an effective medium with a refractive index between that of silicon and silicon oxide. Each trench 60 comprises sides 80 and a bottom 82. A layer 84 with increased doping concentration (relative to the rest of the well 54) runs along the interface (i.e. along the sides 80 and bottom 82 of the trenches 60) between the oxide in the trenches 60 and the silicon in the well 54. The layer with increased doping can reduce the risk of charge carriers generated close to the interface from becoming trapped.

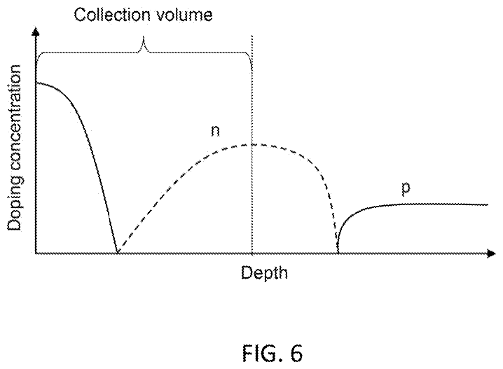

FIG. 6 is schematic graph of the doping profile of the photodiode, with the doping concentration plotted against the depth perpendicular to the surface 62 of the silicon layer 6. The depth starts at the bottom of the trench 60 and runs into the silicon layer 6. The doping concertation falls continuously with depth in the p-doped well 54 towards the pn-junction 56. Charge carriers generated in this region will be pushed by the intrinsic electric field towards the pn-junction 56. The doping concentration decreases continuously from a peak concentration in the p-doped region towards the pn-junction 56, defining a collection volume, within which generated charge carriers are pushed to the pn-junction 56 by the intrinsic electric field.

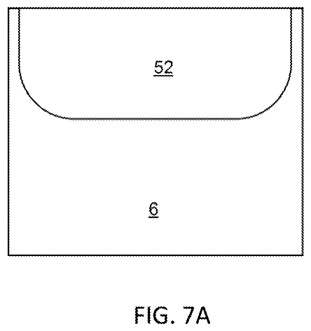

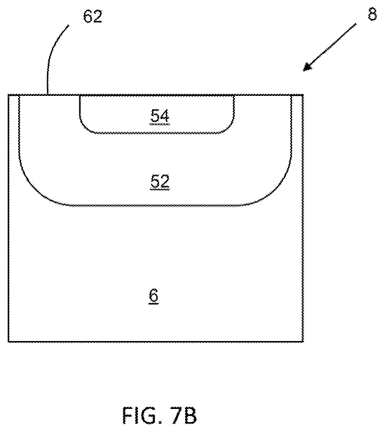

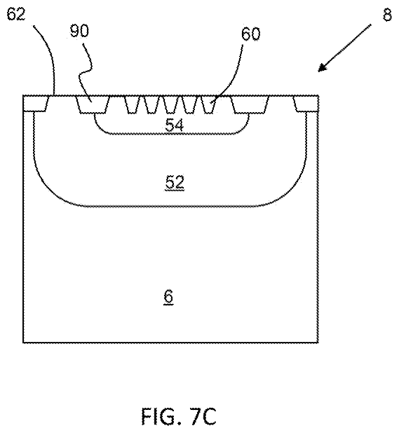

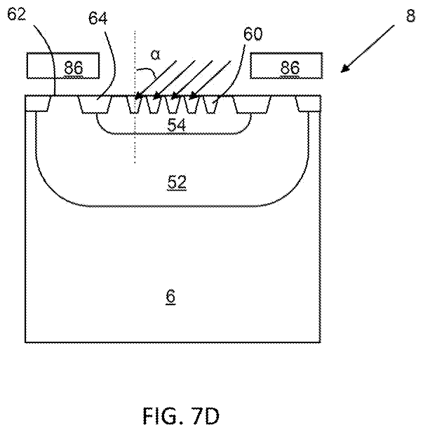

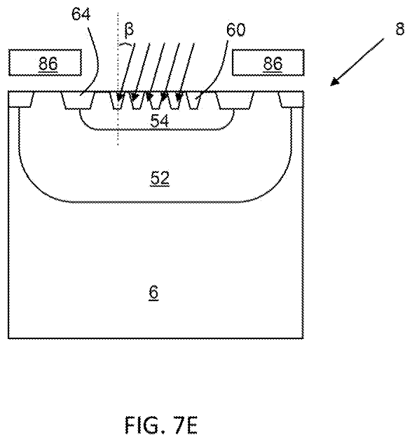

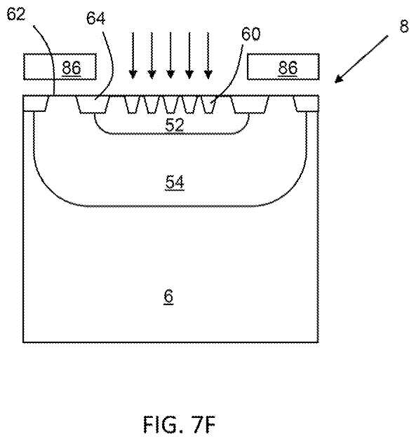

FIGS. 7A to 7F show a sequence of steps of a method of forming a photodiode, such as the photodiode 50 described in relation to FIGS. 5 and 6 above.

FIG. 7A shows the silicon layer 6 with a first well 52 formed. The first well 52 is formed by injecting phosphorus (P) as dopant with an injection energy in the range of 2 MeV to 3 MeV and so as to create a peak concentration in the range of 1e15 cm⁻³ to 1e19 cm⁻³.

FIG. 7B shows the silicon layer 6 after forming the second well 54 at the surface 62 of the silicon layer 6 before STI. The second well 54 is formed by injecting boron (B) with an injection energy in the range of 10 keV to 20 keV and so as to create a peak concentration in the range of 1e14 cm⁻³ to 1e18 cm⁻³.

FIG. 7C shows the silicon layer 6 after forming trenches 60 and 90 in the surface 62 of the silicon layer 6 before filling with oxide. The trenches 90 for isolation and the (smaller) trenches 60 for forming an effective medium are formed using STI technology.

FIG. 7D shows a step of doping wherein BF2 dopants are injected at an angle α and with an injection energy in the range of 20 keV and 30 keV using a mask 86. The doping step is performed after the STI liner oxide anneal (to form a thin layer of silicon oxide in the trenches 60), and before the STI oxide fill (deposition). The angle α of injection is in the range of 30° to 45° so as to dope the sides of the trenches 60. The wafer or injection source is rotated about a normal to the surface 62 and the injection repeated from at least four different directions, to provide uniform doping of the sides around the trenches 60. The injection angle α relative to the normal remains the same for each injection of the doping step.

FIG. 7E shows another step of doping wherein BF2 dopants are injected at another angle β, which is less than the injection angle α of the previous doping step. The doping step is performed before the STI oxide fill (deposition). The doping is performed with an injection energy in the range of 10 keV to 25 keV and is in general less than the injection energy of the previous doping step described in association with FIG. 7D above. The same mask 86 is used in this doping step, as it is the same region of the silicon layer 6 that is being doped. The injection angle β is in the range of 1º to 10° in order to dope the bottom of the trenches 60. The wafer or injection source is rotated about a normal to the surface 62 and the injection repeated from at least four different directions, to provide uniform doping of the bottom of the trenches 60. The injection angle β relative to the normal remains the same for each injection of the doping step. In an alternative embodiment, the injection angle β is set to 0°, in which case the wafer and source do not need to be rotated to achieve uniform doping.

FIG. 7F shows a further step of doping after filling the STI trenches 60, 90. The further step of doping increases the doping concentration at the surface of the silicon layer 6 between the trenches 60.

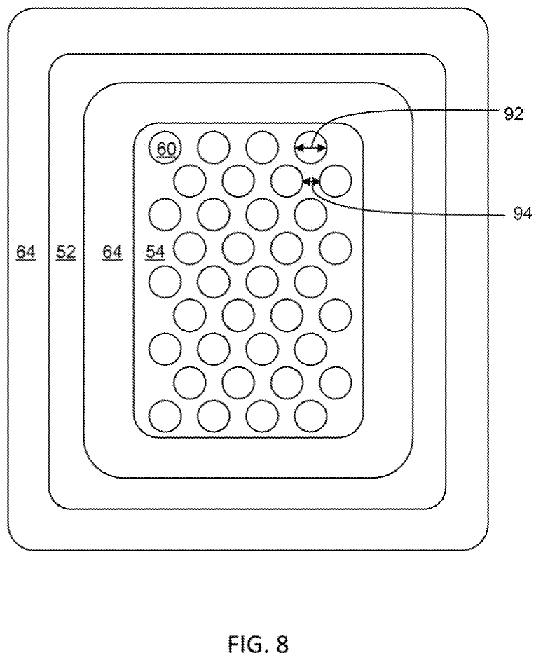

FIG. 8 shows a schematic top view of a part of a photodiode 50. The photodiode 50 comprises an array of trenches 60 being circular holes at the centre arranged to receive incident light. The holes have a width 92 in the range of 220 nm to 350 nm and a spacing 94 between adjacent holes in the range of 70 nm to 210 nm. In general the spacing between the trenches 60 is smaller than the width of the trenches 60. The central (anode) area, corresponding to the underlying p-doped well 54, is surrounded by isolation 64. Outside the isolation 64 is a ring (cathode) area, corresponding to the n-doped well 52, which is in turn surrounded by outer isolation 64. The photodiode may comprise a further outer p-doped anode ring and an n-doped guard ring (not shown).

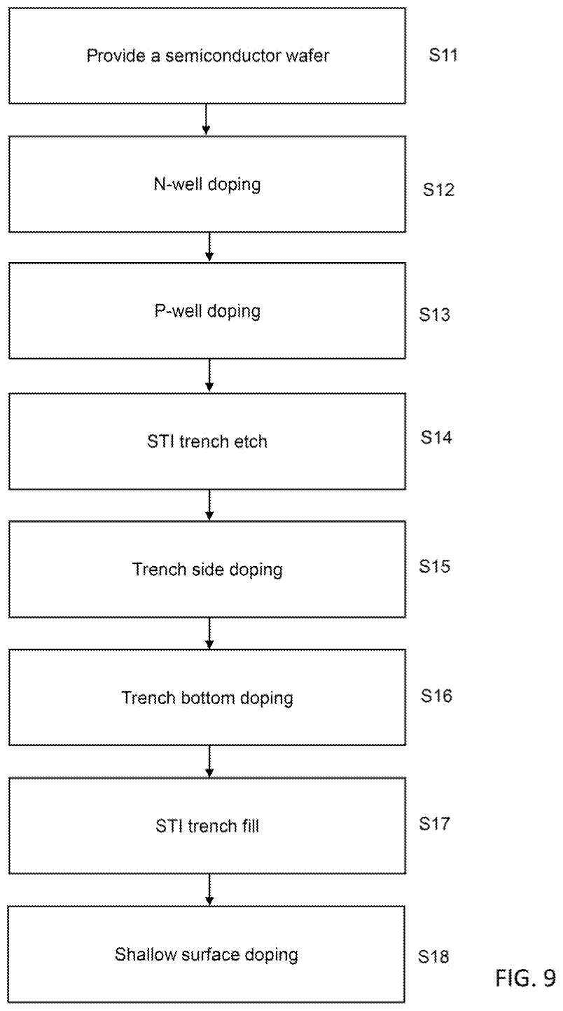

FIG. 9 shows a flow diagram of a method of forming a photodiode. The method comprises providing a semiconductor wafer (step S11). The wafer is a silicon wafer comprising a bulk silicon substrate and a doped epitaxial layer. A first doping step is performed to form an N-well in the epitaxial layer (step S12). After forming the N-well, a second step of doping is performed to form a P-well at the surface of the wafer and thereby form a pn-junction between the P-well and the N-well (step S13). After forming the pn-junction, an STI trench etch is performed to form a plurality of trenches in the P-well in the surface of the wafer (step S14). Before filling the trenches, a third doping step is performed at a relatively high angle with respect to a normal to the surface of the wafer to dope the sides of the trenches (step S15). A fourth doping step at a lesser angle is performed to dope the bottom of the trenches (step S16). After the fourth step of doping, the trenches are filled by oxide deposition (step S17). After filling the trenches, a fifth step of doping is performed to increase the doping in the p-doped well along the surface of the wafer (step S18). The method may comprise further steps as part of a backend of line (BEOL) process for forming anode and cathode contacts in order to apply a voltage across the pn-junction.

In general, the present disclosure provides a method of forming a photodiode. The method may be part of the manufacturing process of a photodetector or imaging device comprising one or more such photodiodes. The method is typically part of a complementary metal oxide semiconductor (CMOS) process, comprising a front end of line (FEOL) process for forming active semiconductor devices such as photodiodes and transistors, and a back end of line (BEOL) process for forming metal layers and contacts to the active semiconductor devices. The method comprises providing a semiconductor wafer, performing a first doping to form a first well in the wafer having a first type of doping, and performing a second doping to form a second well having a second type of doping, so as to form a pn-junction of the photodiode between the first well and the second well. The second step of doping may create a shallow p-well (or n-well) in a top layer of the wafer, which may be referred to as the active layer or diffusion layer and is typically a lightly doped epitaxial layer of silicon. The method further comprises performing a shallow trench isolation (STI) etch to form a plurality of trenches in the surface of the wafer in the second well.

High energy light (e.g. UV light) can change the charge in layers, which in turn can change the electrical field acting in the silicon. This effect causes degradation of photodiode performance from exposure to such light. The described method can provide a photodiode with a strong doping related field, which can lower or completely compensate this effect from UV exposure.

The method comprises performing a third doping by injecting dopants at a first angle relative to the surface of the wafer in order to increase a doping concentration of the second type of doping at along the sides of the trenches in the second well, and performing a fourth doping by injecting dopants at a second angle relative to the surface of the wafer in order to increase a doping concentration of the second type of doping at the bottom of the trenches in the second well. The third and fourth doping are performed after etching the trenches in the semiconductor wafer but before filling the trenches with STI material to provide a more even doping along the interface of the trenches. The method further comprises performing a fifth doping to increase a doping concentration of the second type of doping at the surface of the semiconductor wafer between the trenches in the second well, and forming a first contact for contacting the first well and forming a second contact for contacting the second well in order to apply a voltage across the pn-junction when in use. The contact formation may be part of a CMOS BEOL process further comprising forming a backend stack comprising a plurality of metal layers separated by interdielectric layers.

The first angle may be in the range of 30° to 45° with respect to a normal to the surface. This relatively high angle can allow the dopants to be efficiently injected into the sides (also referred to as sidewalls) of the trenches. The STI etch typically creates trenches (e.g. holes) having sloped sidewalls. The second angle may be in the range of 0° to 15° with respect to a normal to the surface. This relatively small angle is used to dope the substantially flat bottom of the trenches. The first, second and fifth doping may also be performed by injecting dopants having an injection angle in the range of 0° to 15° to the normal (where 0° means injection perpendicular to the surface of the semiconductor wafer). At least the third doping and preferably all doping steps can be performed at four or more different rotation angles about a normal to the surface of the wafer. This can provide a more uniform doping in three dimensions when the injection angle is >0°. In some embodiment, six different (preferably equidistant) rotation angles are used (e.g. at 0°, 60°, 120°, 180°, 240°,300°).

The third doping may comprise injecting the dopants with a first injection energy, while the fourth doping comprises injecting the dopants with a second injection energy, and wherein the first injection energy is greater than the second injection energy. For example, the first injection energy may be in the range of 20 keV to 30 keV, and the second injection energy may be in the range of 10 keV to 25 keV. The dopants for the third and fourth doping may be BF2 molecules.

The first doping may comprise injecting dopants with an injection energy in the range of 2 MeV to 3 MeV. The dopants may be P atoms. The second doping may comprise injecting dopants with an injection energy in the range of 10 keV to 20 keV. The dopants may be B atoms. The fifth doping may comprise injecting dopants with an injection energy in the range of 10 keV to 20 keV. The dopants may be B atoms.

The second, third, fourth and fifth doping steps can be performed using the same mask. The second, third, fourth and fifth doping steps are performed so as to create a continuously falling doping concentration from the trenches to the pn-junction. This can reduce the risk of charge carriers getting trapped or otherwise not reaching the pn-junction for detection.

The semiconductor wafer is typically a silicon wafer comprising an epitaxial layer within which the first well and the second well are formed. In other embodiments, the wafer may be a SOI wafer comprising an epitaxial silicon layer on a buried oxide layer.

The method may further comprise forming a backend stack comprising a plurality of metal layers separated by interdielectric layers, and a nitride passivation layer, and locally removing the nitride passivation layer in a region overlapping the pn-junction (to create a so called UV window).

The trenches may comprise circular or hexagonal holes having a width in the range of 220 nm to 350 nm and a spacing from an adjacent hole in the range of 70 nm to 210 nm. In an alternative embodiment, the trenches may define raised portions (e.g. pillars or spikes) of semiconductor material left in the light sensitive region. The method may further comprise filling the trenches with silicon oxide to form a layer of an effective medium at the surface of the wafer, wherein the effective medium has a wavelength dependent refractive index n between the refractive index of silicon oxide and silicon. An optimal refractive index of the effective medium can be calculated by

$${n}_{1} = \sqrt{{n}_{0} \cdot {n}_{2}} ,$$

Wherein n₀ and n₂ are the refractive indices of the two materials on either side of the effective medium (in this case silicon oxide and silicon respectively). Using the second material (silicon) in forming the effective medium as described herein can be particularly advantageous for forming an effective anti-reflective coating (ARC) layer, as the refractive index of the effective medium will change substantially along with that of the second material. That is the effective medium can have similar wavelength dependence to that of the underlying material.

Also described herein is a semiconductor structure comprising a photodiode formed according to the method described above, and a sensor comprising a plurality of such photodiodes.

A particular advantage of the photodiode may be the increased sensitivity in the UVC range (about 100 nm to 280 nm wavelength) against state-of-the-art CMOS integrated devices and high performance discrete devices. Accordingly, an advantage is the ability to detect weaker signals or to save chip area as the active sensor area can be half as large for the same response and results in half capacitance. The smaller area can also provide a smaller dark current. Another advantage can be that less light is reflected and the collection volume of the device is smaller, so it is less receptive to noise and potentially faster, it may also have a higher linearity range, as the internal resistance is smaller for a similar photocurrent compared to conventional devices.

Embodiments have shown an increased reliability of the response of photodiodes against UV light stress. While most silicon based UV detectors suffer strong degradation from UV light exposure, photodiodes formed according to the described method have shown a significant decrease in such degradation. Hence, the photodiodes can perform well under UV light with little to no measurable degradation.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

1. A method of forming a light sensitive semiconductor structure, the method comprising:
providing a semiconductor wafer comprising a semiconductor layer comprising a light sensitive region;
providing a gate structure comprising an insulation layer on said semiconductor layer and a polysilicon layer on said insulation layer;
providing a contact stop layer on said gate structure, wherein said contact stop layer covers said light sensitive region;
providing an etch mask, said etch mask determining a position and a width of an opening to be formed over said light sensitive region in said contact stop layer;
etching said contact stop layer using said etch mask to form said opening, wherein said polysilicon layer is used as a first etch stopping layer;
etching said polysilicon layer using said etch mask, wherein said insulation layer is used as a second etch stopping layer; and
providing a plurality of metal layers comprising a first metal layer electrically connected to said semiconductor layer and a plurality of dielectric layers between metal layers of said plurality of metal layers.

2. The method according to claim 1, wherein said providing said gate structure comprises thermally growing an oxide layer being said insulation layer and depositing said polysilicon layer on said oxide layer.

3. The method according to claim 1, wherein said providing said contact stop layer comprises depositing one of a silicon nitride layer and a silicon oxynitride layer.

4. The method according to claim 1, wherein said etching said contact stop layer comprises a dry etch.

5. The method according to claim 1, wherein said etching said polysilicon layer comprises a dry etch.

6. The method according to claim 1, further comprising forming metal contacts to connect to said light sensitive region in order to apply a voltage across said light sensitive region, wherein said contact stop layer is used as an etch stopping layer when forming said metal contacts.

7. The method according to claim 1, further comprising providing an anti-reflective coating, ARC, layer over said light sensitive region.

8. The method according to claim 1, further comprising providing insulation around said light sensitive region by shallow trench isolation, STI.

9. The method according to claim 1, further comprising providing a layer of an effective medium having a refractive index between a refractive index of silicon oxide and a refractive index of silicon.

10. The method according to claim 9, wherein said providing said layer of said effective medium comprises shallow trench isolation, STI, in said semiconductor layer.

11. The method according to claim 1, further comprising patterning said polysilicon layer to form a gate in a transistor region of said semiconductor structure.

12. The method according to claim 11, further comprising forming a metal contact to connect to said gate, wherein said contact stop layer is used to as an etch stopping layer when forming said metal contact.

13. A semiconductor structure comprising:
a photodiode comprising a light sensitive region in a semiconductor layer;
a gate structure comprising an insulation layer located on said semiconductor layer and a polysilicon layer located on said insulation layer;
a contact stop layer located on said polysilicon layer;
an opening in said contact stop layer and in said polysilicon layer located over at least a part of said light sensitive region; and
a plurality of metal layers comprising a first metal layer electrically connected to said semiconductor layer and a plurality of dielectric layers between metal layers of said plurality of metal layers.

14. The semiconductor structure according to claim 13, wherein said contact stop layer comprises one of a silicon nitride layer and a silicon oxynitride layer.

15. The semiconductor structure according to claim 13, further comprising a transistor wherein a gate of said transistor comprises a part of said gate structure.
